(19) United States
(12) Patent Application Publication
(10) Pub. No.: US 2026/0171018 A1
(43) Pub. Date: Jun. 18, 2026

(54) DISPLAY APPARATUS

(71) Applicant: LG Display Co., Ltd., Seoul (KR)

(72) Inventors: SANG-IL SHIN, Paju-si (KR); TAEKYUN KIM, Paju-si (KR)

(73) Assignee: LG Display Co., Ltd., Seoul (KR)

(21) Appl. No.: 19/345,850

(22) Filed: Sep. 30, 2025

(30) Foreign Application Priority Data
Dec. 12, 2024 (KR) 10-2024-0184835

(51) Int. Cl. G09G 3/3233

(52) U.S. Cl. CPC G09G 3/3233; G09G 2300/0426; G09G 2300/0819; G09G 2300/0842; G09G 2320/0233

(57) ABSTRACT

A display apparatus can include a tandem light-emitting element having first and second light-emitting elements connected in series, and a reset transistor configured to apply a reset voltage to a node between the first and second light-emitting elements corresponding to a charge generation layer of the tandem light-emitting element. By resetting the charge generation layer of the tandem light-emitting element, it is possible to prevent or minimize voltage fluctuation of the charge generation layer.

### CROSS-REFERENCE TO RELATED APPLICATION

The present application claims priority to Korean Patent Application No. 10-2024-0184835, filed in the Republic of Korea on Dec. 12, 2024, the entire contents of which is hereby expressly incorporated by reference into the present application.

### BACKGROUND

### Field

The present disclosure relates to a display apparatus.

### Discussion of the Related Art

An organic light-emitting display apparatus is a self-emissive display device that, unlike a liquid crystal display, requires no separate light source, and enables lightweight and thin manufacturing. Additionally, the organic light-emitting display apparatus offers advantages in power consumption due to low-voltage driving and excels in color reproduction, response speed, viewing angle, and contrast ratio (CR), and is positioned to be a next-generation display under research.

Display apparatuses are continuously improved to enhance screen resolution and luminance, delivering clearer images to users.

### SUMMARY OF THE DISCLOSURE

An organic light-emitting display apparatus employs an organic light-emitting element having a tandem structure to enhance lifespan and efficiency. In this tandem structure, the organic light-emitting element includes a first light-emitting layer, a charge generation layer (CGL), and a second light-emitting layer, which are disposed between an anode and a cathode.

However, some display apparatuses according to the related art can suffer from unwanted light emission which can be caused by fluctuations in the CGL voltage, which result from residual charges remaining in the CGL after emission, leakage asymmetry between first and second light-emitting layers, or lateral leakage current from adjacent pixels.

To address this issue, the inventors of the present disclosure have developed an improved display apparatus that prevents or minimizes unwanted light emission due to CGL voltage fluctuations, thereby improving image quality.

An objective of an embodiment of the present disclosure is to provide a display apparatus capable of improving image quality by preventing or minimizing unwanted light emission which can be caused by CGL voltage fluctuations in a light-emitting element having a tandem structure.

The objectives of one or more embodiments of the present disclosure are not limited to those mentioned above, and other objectives not mentioned will be clearly understood by those skilled in the art from the detailed description.

A display apparatus according to an embodiment of the present disclosure can include a tandem light-emitting element comprising first and second light-emitting elements connected in series, and can further include a reset transistor configured to apply a reset voltage to a node between the first and second light-emitting elements corresponding to a charge generation layer of the tandem light-emitting element, thereby allowing the charge generation layer of the tandem light-emitting element to be reset.

A display apparatus according to an embodiment of the present disclosure is advantageous in eliminating the effects of parasitic capacitance or parasitic resistance in the tandem light-emitting element by resetting the charge generation layer of the tandem light-emitting element.

In addition, the display apparatus according to embodiments of the present disclosure is advantageous in eliminating the effects of lateral leakage current flowing from adjacent pixels by resetting the charge generation layer of the tandem light-emitting element.

In addition, the display apparatus according to embodiments of the present disclosure is advantageous in reducing luminance differences between the first and second light-emitting elements at the initial time of displaying a gray pattern following a black pattern by preventing voltage fluctuations in the charge generation layer of the tandem light-emitting element.

In addition, the display apparatus according to embodiments of the present disclosure is advantageous in minimizing the potential difference between the first and second light-emitting elements by preventing voltage fluctuations in the charge generation layer of the tandem light-emitting element, thereby preventing unwanted light emission from occurring in the first and second light-emitting elements.

In addition, the display apparatus according to embodiments of the present disclosure is advantageous in preventing voltage fluctuations in the charge generation layer by resetting the charge generation layer of the tandem light-emitting element using an anode reset voltage during the bias period of a refresh frame and an anode reset frame.

In addition, the display apparatus according to embodiments of the present disclosure is advantageous in improving image quality by preventing voltage fluctuations in the charge generation layer, enabling pixels to emit light at the target luminance.

In addition to the aforementioned effects, other advantageous effects of the present invention will be provided along with the detailed description of the invention.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a block diagram schematically illustrating an organic light-emitting display apparatus according to an embodiment of the present disclosure;

FIG. 2 is a cross-sectional view illustrating the stacked structure of an organic light-emitting display apparatus according to an embodiment of the present disclosure;

FIG. 3 is a cross-sectional view illustrating the schematic stacked structure of a tandem light-emitting element in an organic light-emitting display apparatus according to an embodiment of the present disclosure;

FIG. 4 is a circuit diagram of a pixel in an organic light-emitting display apparatus according to an embodiment of the present disclosure;

FIG. 5 illustrates an equivalent circuit of the tandem light-emitting element of FIG. 4; and

FIG. 6 shows diagrams illustrating the process flow of depositing a charge generation layer (CGL) on a refresh electrode in FIG. 2.

### DETAILED DESCRIPTION OF THE EMBODIMENTS

Advantages and features disclosed in the present disclosure and methods of accomplishing the same can be understood more readily by reference to the detailed description of embodiments that will be made hereinafter with reference to the accompanying drawings. However, the present disclosure is not limited to the embodiments disclosed below and can be implemented in various different forms; these embodiments are provided merely to ensure that the present disclosure is complete and to fully inform those of ordinary skill in the art of the scope of the invention.

The shapes, sizes, ratios, angles, numbers and the like illustrated in the drawings to describe embodiments of the present disclosure are merely examples, and thus, the present disclosure is not limited thereto. Throughout the specification, the same reference numerals refer to the same components. In addition, detailed descriptions of well-known technologies can be omitted in the present disclosure to avoid obscuring the subject matter of the present disclosure. When terms such as "comprises," "has," "includes," or "is made up of" are used in this specification, it should be understood that unless "only" is specifically used, additional elements or steps can be included. Unless otherwise explicitly stated, when a component is expressed in the singular form, it is intended to encompass the plural form as well.

In interpreting the components, it is construed to include a margin of error even in the absence of explicit description.

In the case of describing positional relationships, for example, when the positional relationship between two components is described using terms such as “on,’ “on top of,” “below,” or “beside,” one or more other components can be positioned between the two components unless “directly” or “immediately” is specified.

When describing temporal relationships, expressions such as "after," "following," "next," or "before" can indicate a sequence of events, and unless "immediately" or "directly" is used, non-continuous cases can also be included.

When describing a signal flow relationship, for example, in the case of "a signal is transmitted from node A to node B," instances where the signal is transmitted from node A to node B via another node can also be included unless "immediately" or "directly" is specified.

Terms like "first," "second," etc., are used to describe various components, but these components are not limited by these terms. These terms are merely used for distinguishing one component from the other components and may not define order or sequence. Therefore, the first component mentioned hereinafter can be the second component in the technical sense of the present disclosure. Further, the term “can” fully encompasses all the meanings and coverages of the term “may” and vice versa.

The various features of the embodiments of the disclosure can combined or assembled together, either partially or entirely, in a technically diverse manner, and each embodiment can be independently implemented or in conjunction with related embodiments.

Hereinafter, a display apparatus capable of improving image quality by preventing unwanted light emission caused by voltage fluctuations in the CGL of a light-emitting element having a tandem structure according to embodiments of the present disclosure is discussed. All the components of each display apparatus/device according to all embodiments of the present disclosure are operatively coupled and configured.

Various embodiments of the present disclosure will now be described in detail with reference to the accompanying drawings.

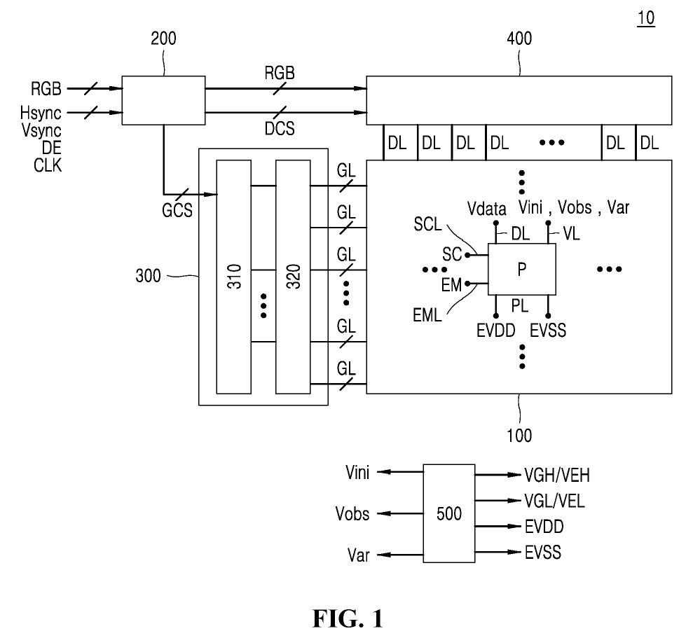

FIG. 1 is a block diagram schematically illustrating an organic light-emitting display apparatus according to an embodiment of the present disclosure.

Referring to FIG. 1, a display apparatus 10 includes a display panel 100 including a plurality of pixels P, a controller 200, a gate driver 300 supplying scan signals SC to the plurality of pixels P, a data driver 400 supplying data voltages Vdata to the plurality of pixels P, and a power supply 500 providing voltages required for driving the plurality of pixels P.

In the display panel 100, a plurality of gate lines GL and a plurality of data lines DL intersect each other, and each of the plurality of pixels P is connected to a gate line GL and a data line DL. Specifically, one pixel P receives a gate signal from the gate driver 300 via a gate line GL, a data signal from the data driver 400 via a data line DL, and a high-potential driving voltage EVDD and a low-potential driving voltage EVSS from the power supply 500.

The gate line GL supplies a scan signal SC and an emission control signal EM, and the data line DL supplies a data voltage Vdata. Additionally, depending on various embodiments, the gate line GL can include a plurality of scan lines SCL supplying scan signals SC and an emission control line EML supplying emission control signals EM. Additionally, the plurality of pixels P can further include a power line VL to receive a bias voltage Vobs, an initialization voltage Vini, and an anode reset voltage Var.

Moreover, each pixel P includes a light-emitting element and a pixel circuit. The pixel circuit includes a plurality of switching elements, a driving element, and a capacitor. Here, the switching elements and driving element can be composed of thin-film transistors. In the pixel circuit, the driving element controls the current supplied to the light-emitting element based on the data voltage, thereby adjusting the light emission amount of the light-emitting element. Additionally, the plurality of switching elements receive a scan signal SC supplied via the plurality of scan lines SCL and an emission control signal EM supplied via the emission control line EML to operate the pixel circuit.

The display panel 100 can be implemented as a non-transmissive display panel or a transmissive display panel. A transmissive display panel can be applied to a transparent display device where an image is displayed on the screen and real objects in the background are visible. The display panel 100 can be fabricated as a flexible display panel. A flexible display panel can be implemented as an OLED panel using a plastic substrate.

Touch sensors can be disposed on the display panel 100. Touch input can be sensed using separate touch sensors or through the pixels P. The touch sensors can be implemented as on-cell type or add-on type touch sensors disposed on the screen of the display panel, or as in-cell type touch sensors embedded in the display panel 100.

The controller 200 processes image data RGB input from an external source to match the size and resolution of the display panel 100 and supplies it to the data driver 400. The controller 200 generates a gate control signal GCS and a data control signal DCS using synchronization signals input from an external source, such as a clock signal CLK, a data enable signal DE, a horizontal synchronization signal Hsync, and a vertical synchronization signal Vsync. The controller 200 supplies the gate control signal GCS and the data control signal DCS to the gate driver 300 and the data driver 400, respectively, thereby controlling the gate driver 300 and the data driver 400.

The controller 200 can be combined with various processors, such as a microprocessor, a mobile processor, or an application processor, depending on the device in which it is implemented.

The host system can be any one of a TV system, a set-top box, a navigation system, a personal computer PC, a home theater system, a mobile device, a wearable device, or a vehicle system.

The controller 200 can control the operation timing of the gate driver 300 and the data driver 400 at a frame frequency of input frame frequency × i (where i is a positive integer greater than 0) Hz by multiplying the input frame frequency by i. The input frame frequency is 60 Hz in the NTSC (National Television Standards Committee) system and 50 Hz in the PAL (Phase-Alternating Line) system.

The controller 200 generates signals to enable the pixel P to be driven at various refresh rates. The refresh rate can be defined as the number of frames transmitted per second. For example, the controller 200 generates signals related to driving such that the pixel P can be driven at a variable refresh rate when operating in a Variable Refresh Rate VRR mode, allowing switching to different refresh rates. For example, the controller 200 can simply change the speed of the clock signal or generate a synchronization signal to include a horizontal blank or vertical blank.

Based on timing signals Vsync, Hsync, and DE received from the host system, the controller 200 generates a gate control signal GCS to control the operation timing of the gate driver 300 and a data control signal DCS to control the operation timing of the data driver 400. The controller 200 synchronizes the gate driver 300 and the data driver 400 by controlling their operation timing.

The voltage level of the gate control signal GCS output from the controller 200 can be converted into a gate-on voltage VGL, VEL and a gate-off voltage VGH, VEH through a level shifter and supplied to the gate driver 300. The level shifter converts a low-level voltage of the gate control signal GCS into a gate low voltage VGL and a high-level voltage of the gate control signal GCS into a gate high voltage VGH. The gate control signal GCS includes a start pulse and a shift clock.

The gate driver 300 supplies scan signals SC to the gate line GL in response to the gate control signal GCS supplied from the controller 200. The gate driver 300 can be disposed on one side or both sides of the display panel 100 using a Gate In Panel GIP configuration.

The gate driver 300 sequentially outputs gate signals to the plurality of gate lines GL under the control of the controller 200. The gate driver 300 can sequentially supply the gate signals to the gate lines GL by shifting the gate signals using a shift register.

The gate signal can include a scan signal SC and an emission control signal EM in an organic light-emitting display apparatus. The scan signal SC includes a scan pulse that swings between a gate-on voltage VGL and a gate-off voltage VGH. The emission control signal EM can include an emission control signal pulse that swings between a gate-on voltage VEL and a gate-off voltage VEH. The scan pulse, synchronized with the data voltage Vdata, is used to select the pixels P of the line where data is to be written. The emission control signal pulse defines the emission time of the pixels P.

The gate driver 300 includes an emission control signal driver 310 and at least one scan driver 320. The emission control signal driver 310 outputs an emission control signal pulse in response to a start pulse and a shift clock from the controller 200 and sequentially shifts the emission control signal pulse according to the shift clock. The scan driver 320 outputs a scan pulse in response to a start pulse and a shift clock from the controller 200 and shifts the scan pulse in accordance with the shift clock timing.

The data driver 400 converts image data RGB into a data voltage Vdata in response to the data control signal DCS supplied from the controller 200 and supplies the converted data voltage Vdata to the pixels P through the data line DL.

In FIG. 1, the data driver 400 is illustrated as being disposed on one side of the display panel 100 in a single form, but the number and arrangement position of the data driver 400 are not limited thereto. The data driver 400 can be composed of a plurality of integrated circuits IC arranged separately on one side of the display panel 100.

The power supply 500 uses a DC-DC converter to generate the DC power required for driving the pixel array of the display panel 100, the gate driver 300, and the data driver 400. The DC-DC converter can include a charge pump, a regulator, a buck converter, a boost converter, and the like. The power supply 500 can receive a direct current input voltage from a host system and generate direct current voltages such as a gate-on voltage VGL and VEL, a gate-off voltage VGH/VEH, a high-potential driving voltage EVDD, and a low-potential driving voltage EVSS. The gate-on voltage VGL and VEL and gate-off voltage VGH and VEH are supplied to the level shifter and gate driver 300. The high-potential driving voltage EVDD and the low-potential driving voltage EVSS are supplied to the pixels P.

Additionally, the power supply 500 can generate direct current voltages such as the initialization voltage Vini, bias voltage Vobs, and anode reset voltage Var. The initialization voltage Vini, bias voltage Vobs, and anode reset voltage Var are supplied to the pixel P through the power line VL. Here, the power line VL can include a bias voltage bus line, an anode reset voltage bus line, and an initialization voltage bus line.

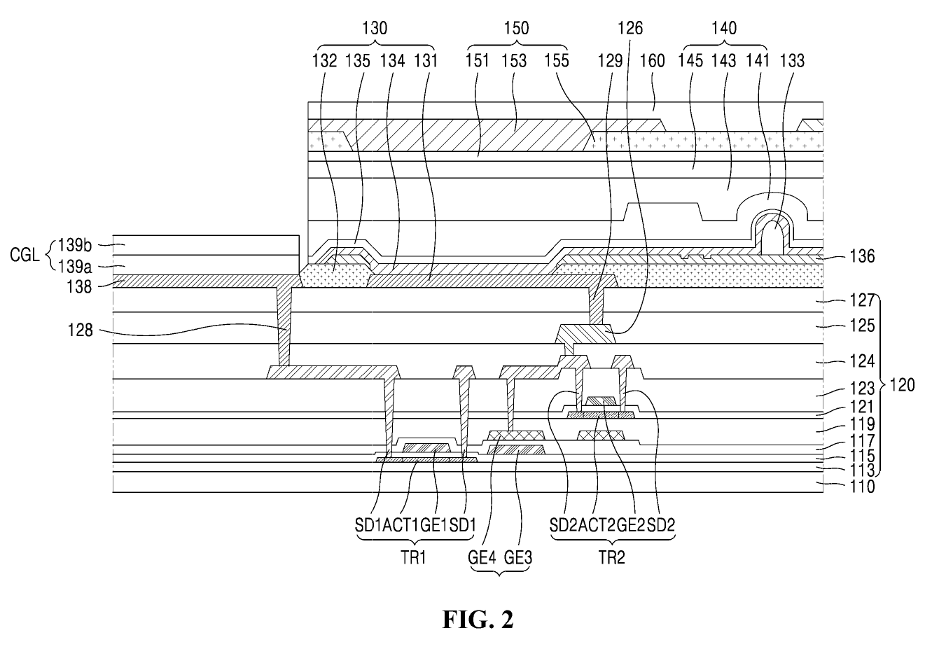

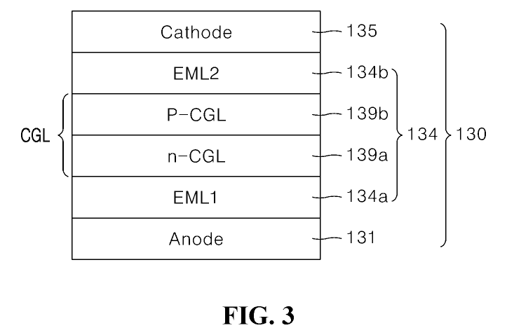

FIG. 2 is a cross-sectional view illustrating the stacked structure of an organic light-emitting display apparatus according to an embodiment of the present disclosure. FIG. 3 is a cross-sectional view illustrating the schematic stacked structure of a tandem light-emitting element in an organic light-emitting display apparatus according to an embodiment of the present disclosure.

Referring to FIG. 2, the organic light-emitting display apparatus includes a substrate 110, a transistor array layer 120, a light-emitting array layer 130, an encapsulation layer 140, a color filter array layer 150, and an optical carrier layer 160.

A transistor array layer 120 can be disposed on the substrate 110. The transistor array layer 120 can include a plurality of thin-film transistors, a plurality of scan lines, and a plurality of data lines.

A light-emitting array layer 130 can be disposed on the transistor array layer 120. The light-emitting array layer 130 can include a light-emitting element composed of a first electrode 131, a light-emitting layer 134, and a second electrode 135. The light-emitting layer 134 can be an organic light-emitting layer including an organic material, but embodiments of the present disclosure are not limited thereto. A driving current can be applied to the first electrode 131 and the second electrode 135, disposed above and below the light-emitting layer 134, to cause the light-emitting layer to emit light. The light-emitting element has a tandem structure, which will be described later with reference to FIG. 3.

The encapsulation layer 140 can be disposed on the light-emitting array layer 130. Since the organic light-emitting layer includes an organic material, it can be vulnerable to oxygen and moisture. Thus, the encapsulation layer 140 can seal the organic light-emitting layer including the organic material to prevent infiltration of oxygen or moisture. The encapsulation layer 140 can include an inorganic insulating layer or an organic insulating layer having a multilayer structure.

The color filter array layer 150 can be disposed on the encapsulation layer 140. A blocking layer 155 is disposed between the color filters 153 of the color filter array layer 150. The blocking layer 155 serves to delineate each sub-pixel region and prevent optical interference and light leakage between adjacent sub-pixel regions. The blocking layer 155 can be formed of a high-resistance black insulating material.

An optical carrier layer 160 is formed on the color filters 153 and the blocking layer 155. The optical carrier layer 160 planarizes the substrate 110 on which the color filters 153 and the blocking layer 155 are formed.

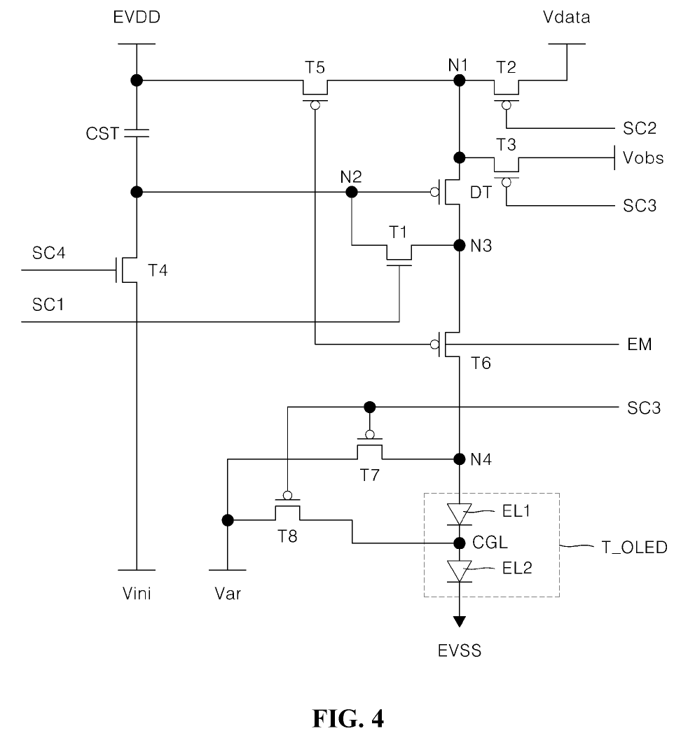

A first transistor TR1 can be disposed on the substrate 110. The first transistor TR1 can include a first semiconductor layer ACT1, a first gate electrode GE1, and a first source and drain electrode SD1. The first transistor TR1 can correspond to the eighth transistor T8 (for example, sometimes referred to as a reset transistor) shown in FIG. 4.

A first buffer layer 113 can be disposed between the substrate 110 and the first transistor TR1. The first buffer layer 113 can be disposed on the substrate 110 and can cover the surface of the substrate 110. For example, the first buffer layer 113 can entirely cover the surface of the substrate 110. The first buffer layer 113 can protect the first transistor TR1 by reducing or preventing the infiltration of moisture, oxygen, or impurities through the substrate 110. The first buffer layer 113 can include multiple layers. The first buffer layer 113 can include an inorganic insulating film comprising silicon oxide (SiOx) or silicon nitride (SiNx). For example, the first buffer layer 113 can be formed as a multilayer structure in which one or more inorganic insulating films are alternately stacked.

The first semiconductor layer ACT1 of the first transistor TR1 can include a silicon-based semiconductor material. For example, the first semiconductor layer ACT1 can include polysilicon or low-temperature polysilicon. For example, the first semiconductor layer ACT1 can include an oxide semiconductor material. Accordingly, the first semiconductor layer ACT1 of the first transistor TR1 can be composed of an oxide semiconductor layer, a low-temperature polysilicon semiconductor layer, or a combination thereof.

The first semiconductor layer ACT1 can include a channel region and source and drain regions. The region of the first semiconductor layer ACT1 overlapping the first gate electrode GE1 can be the channel region. For example, the region of the first semiconductor layer ACT1 overlapping the first gate electrode GE1 in the upper and lower directions can be the channel region. The source and drain regions can be disposed on both sides of the channel region, respectively.

A first insulating layer 115 can be disposed between the first semiconductor layer ACT1 and the first gate electrode GE1. The first insulating layer 115 can be formed of a single layer or a plurality of layers of silicon oxide (SiOx) or silicon nitride (SiNx). The first insulating layer 115 can be a gate insulating layer.

The first gate electrode GE1 can be formed of a single layer or a multilayer structure composed of one of molybdenum (Mo), aluminum (Al), chromium (Cr), gold (Au), titanium (Ti), nickel (Ni), neodymium (Nd), and copper (Cu), or an alloy thereof.

A second insulating layer 117 can be disposed on the first gate electrode GE1. The second insulating layer 117 can cover the first gate electrode GE1. The second insulating layer 117 can include an inorganic insulating material. The second insulating layer 117 can be an interlayer insulating layer.

A first protective layer 119 can be disposed on the second insulating layer 117. The first protective layer 119 can include an inorganic insulating film containing silicon oxide (SiOx) or silicon nitride (SiNx). The first protective layer 119 can be a first passivation layer. A second transistor TR2 can be disposed on the first protective layer 119.

The second transistor TR2 can include a second semiconductor layer ACT2, a second gate electrode GE2, and second source and drain electrodes SD2. The second transistor TR2 can be the driving transistor DT shown in FIG. 4.

The second semiconductor layer ACT2 of the second transistor TR2 can include an oxide semiconductor material. For example, the second semiconductor layer ACT2 can include an oxide semiconductor material such as indium-gallium-zinc-oxide (IGZO) or indium-zinc-oxide (IZO). Alternatively, the second semiconductor layer ACT2 can include a silicon-based semiconductor material. For example, the silicon-based semiconductor material can be polysilicon or low-temperature polysilicon.

The second semiconductor layer ACT2 can include a channel region and source and drain regions. A region of the second semiconductor layer ACT2 overlapping the second gate electrode GE2 can be a channel region. For example, the region of the second semiconductor layer ACT2 overlapping the second gate electrode GE2 in the vertical direction can be a channel region. The source and drain regions can be disposed on both sides of the channel region, respectively. Accordingly, the second semiconductor layer ACT2 of the second transistor TR2 can be composed of one of an oxide semiconductor layer and a low-temperature polysilicon semiconductor layer, or a combination thereof.

A third insulating layer 121 can be disposed between the second semiconductor layer ACT2 and the second gate electrode GE2. The third insulating layer 121 can be formed of a single layer or a plurality of layers of silicon oxide (SiOx) or silicon nitride (SiNx).

The second gate electrode GE2 can be disposed on the third insulating layer 121. The second gate electrode GE2 can be formed of a single layer or multiple layers made of one of molybdenum (Mo), aluminum (Al), chromium (Cr), gold (Au), titanium (Ti), nickel (Ni), neodymium (Nd), and copper (Cu), or an alloy thereof.

A fourth insulating layer 123 can be disposed on the second gate electrode GE2. The fourth insulating layer 123 can cover the second gate electrode GE2. The fourth insulating layer 123 can include an inorganic insulating material. For example, the fourth insulating layer 123 can include silicon oxide (SiOx) or silicon nitride (SiNx). The fourth insulating layer 123 can be an interlayer insulating layer.

Second source and drain electrodes SD2 can be disposed on the fourth insulating layer 123. The second source and drain electrodes SD2 can be electrically connected to the source and drain regions of the second semiconductor layer ACT2 through contact holes passing through the fourth insulating layer 123 and the third insulating layer 121.

The second source and drain electrodes SD2 can be formed as a multilayer structure composed of molybdenum (Mo), aluminum (Al), chromium (Cr), gold (Au), titanium (Ti), nickel (Ni), neodymium (Nd), copper (Cu), or an alloy thereof.

Between the second insulating layer 117 and the second semiconductor layer ACT2, a light-shielding layer can be further included. The light-shielding layer can block external light incident on the second semiconductor layer ACT2.

A capacitor Cst can be disposed on the first insulating layer 115. The capacitor Cst can include a third gate electrode GE3 and a fourth gate electrode GE4. The second insulating layer 117 can be disposed between the third gate electrode GE3 and the fourth gate electrode GE4. At least one of the third gate electrode GE3 or the fourth gate electrode GE4 can be electrically connected to an electrode of the second transistor TR2. The capacitor Cst can be electrically connected to the second transistor TR2 through a connection electrode.

A second protective layer 124 can be disposed on the second source and drain electrodes SD2. The second protective layer 124 can include an inorganic insulating film containing silicon oxide (SiOx) or silicon nitride (SiNx). The second protective layer 124 can serve as a second passivation layer.

Planarization layers 125 and 127 can be disposed on the second protective layer 124. The planarization layers 125 and 127 can include a first planarization layer 125 and a second planarization layer 127.

The first planarization layer 125 can planarize the step difference generated by underlying circuit elements including the first and second transistors TR1 and TR2. The first planarization layer 125 can include an organic insulating material such as an acrylic resin, epoxy resin, phenolic resin, polyamide resin, or polyimide resin.

The first contact electrode 126 can contact and fill a contact hole with the second source and drain electrodes SD2. While filling the contact hole, the first contact electrode 126 can extend partially onto the surface of the first planarization layer 125.

A contact hole passing through the second planarization layer 127 can be filled with a second contact electrode 129, one surface of which can connect to the first contact electrode 126 to establish electrical connection.

A light-emitting array layer 130 can be disposed on the second planarization layer 127. The light-emitting array layer 130 can include banks 132 and 136, light-emitting elements, and spacers 133. Each light-emitting element can include a first electrode 131, a light-emitting layer 134, and a second electrode 135. The first electrode 131 can serve as an anode electrode, and the second electrode 135 can serve as a cathode electrode.

The first electrode 131 can be disposed on the second planarization layer 127. One surface of the first electrode 131 can contact the upper surface of the second contact electrode 129. Accordingly, the first electrode 131 can be electrically connected to the second source or drain electrodes SD2 of the second transistor TR2 via the second contact electrode 129 and the first contact electrode 126.

The first electrode 131 can include a metal oxide such as indium tin oxide ITO or indium zinc oxide IZO. Alternatively, the first electrode 131 can include a reflective metal film—formed as a single-layer or multilayer structure—composed of silver (Ag), aluminum (Al), gold (Au), nickel (Ni), chromium (Cr), or their compounds.

Banks 132 and 136 can be disposed on the second planarization layer 127. These can include a first bank 132 and a second bank 136, which together define each pixel P. For this purpose, the first bank 132 can be formed to cover the edges of the first electrode 131. Additionally, the first bank 132 can prevent light of different colors from mixing and being emitted between adjacent pixels.

The first bank 132 can include an organic insulating film such as polyimide resin or epoxy resin. For example, the first bank 132 can be made of a material containing black pigment, or of an organic material such as benzocyclobutene resin, epoxy resin, polyimide resin, acrylic resin, or a photosensitive polymer.

A spacer 133 can be disposed on the banks 132 and 136. The spacer 133 can protect the light-emitting layer 134 by preventing it from directly receiving external impact.

Referring to FIGS. 2 and 3, the light-emitting layer 134 can be disposed on the first electrode 131. In one embodiment, the light-emitting layer 134 can include an organic material that emits different colors in each pixel. For example, the light-emitting layer 134 can emit one of red, green, blue, or white colors. In another embodiment, the light-emitting layer 134 can be formed of an organic material that emits white light, and a color filter 153 can allow one of red, green, or blue colors to be displayed.

The light-emitting layer 134 can have a stacked structure including a hole transporting layer (HTL), an emission material layer (EML), an electron transporting layer (ETL), a hole blocking layer (HBL), a hole injecting layer (HIL), an electron blocking layer (EBL), and an electron injecting layer (EIL).

When the light-emitting element includes the stacked structure, the stack can include one or more such structures. For example, a charge generation layer CGL can be further included between two or more stacked structures. The charge generation layer CGL can include an N-type charge generation layer 139a and a P-type charge generation layer 139b.

For example, in the case of a tandem-type light-emitting element, a first light-emitting layer 134a can be disposed on the first electrode 131, a charge generation layer CGL can be disposed on the first light-emitting layer 134a, a second light-emitting layer 134b can be disposed on the charge generation layer CGL, and the second electrode 135 can be disposed on the second light-emitting layer 134b. Here, the first electrode 131 can be an anode electrode, and the second electrode 135 can be a cathode electrode. Each of the first light-emitting layer 134a and the second light-emitting layer 134b can include a hole transporting layer (HTL), an emission material layer (EML), an electron transporting layer (ETL), a hole blocking layer (HBL), a hole injecting layer (HIL), an electron blocking layer (EBL), and an electron injecting layer (EIL). The charge generation layer CGL can include an N-type charge generation layer 139a and a P-type charge generation layer 139b.

The charge generation layer CGL serves to divide the voltage, sharing the light-emitting burden between the upper and lower layer elements. For example, the N-type charge generation layer 139a and the P-type charge generation layer 139b can facilitate the injection of electrons into the electron transporting layer (ETL) and the injection of holes into the hole transporting layer (HTL), respectively. The tandem structure of the light-emitting element plays a role in enhancing photon emission by electrons and holes through the charge generation layer CGL. The tandem structure of the light-emitting element can improve the lifespan and current efficiency of the organic light-emitting element, and since two light-emitting layers emit light together, it can compensate for deficiencies in image quality, such as luminance.

The first and second emission material layers EML1 and EML2 of the light-emitting layer 134 can emit light through recombination of holes injected from the first electrode 131 and electrons injected from the second electrode 135. The light-emitting layer 134 can be formed across the entire display area, covering the exposed surfaces of the first electrode 131 and the bank 132.

A second electrode 135 can be disposed on the light-emitting layer 134. The second electrode 135 can be formed to cover the light-emitting layer 134. The second electrode 135 can be commonly formed over a plurality of pixels P. The second electrode 135 can include a metal oxide such as indium tin oxide (ITO) or indium zinc oxide (IZO). Alternatively, the second electrode 135 can include a single-layer or multi-layer structure comprising a reflective metal film formed of silver (Ag), aluminum (Al), gold (Au), nickel (Ni), chromium (Cr), or compounds thereof.

A third contact electrode 128 can fill a contact hole while being in contact with one surface of the first source or drain electrode SD1. The contact hole that penetrates the second protective layer 124 and the first and second planarization layers 125 and 127 can be filled with the third contact electrode 128, and one surface of the third contact electrode 128 can be connected to the first source or drain electrode SD1 of the first transistor TR1 to be electrically connected thereto.

A refresh electrode 138 can be disposed on the second planarization layer 127. One surface of the refresh electrode 138 can be in contact with an upper surface of the third contact electrode 128. Accordingly, the refresh electrode 138 can be electrically connected to the first source or drain electrode SD1 of the first transistor TR1 through the third contact electrode 128. The refresh electrode 138 can be formed in the same layer as the first electrode 131.

An N-type charge generation layer 139a can be disposed on the refresh electrode 138. A P-type charge generation layer 139b can be disposed on the N-type charge generation layer 139a. The N-type charge generation layer 139a disposed on the refresh electrode 138 can be electrically connected to the N-type charge generation layer 139a disposed in the light-emitting layer 134, and the P-type charge generation layer 139b disposed on the refresh electrode 138 can be electrically connected to the P-type charge generation layer 139b disposed in the light-emitting layer 134.

The charge generation layer CGL can be reset by an anode reset voltage Var applied through the refresh electrode 138, which is electrically connected to the first source or drain electrode SD1 of the first transistor TR1.

The encapsulation layer 140 can be disposed on the light-emitting element. The encapsulation layer 140 can protect the light-emitting element from external oxygen or moisture. The encapsulation layer 140 can cover the display area and extend to the non-display area surrounding the display area. For example, the encapsulation layer 140 can be located in the display area and can extend to the non-display area around the display area.

The encapsulation layer 140 can include a multilayer structure in which a first encapsulation layer 141, a second encapsulation layer 143, and a third encapsulation layer 145 are disposed.

The first encapsulation layer 141 can be disposed on the second electrode 135. The first encapsulation layer 141 can include an inorganic insulating material. For example, the first encapsulation layer 141 can include at least one inorganic insulating material among silicon nitride (SiNx), silicon oxide (SiOx), and silicon oxynitride (SiON).

The second encapsulation layer 143 can be disposed on the first encapsulation layer 141. The second encapsulation layer 143 can cover the first encapsulation layer 141 and can have a sufficient thickness to provide a flat surface. The second encapsulation layer 143 can prevent foreign substances from penetrating into the light-emitting element. The second encapsulation layer 143 can include an organic insulating material. For example, the second encapsulation layer 143 can include at least one of epoxy, polyimide, polyethylene, or acrylate.

A third encapsulation layer 145 can be disposed on the second encapsulation layer 143. The third encapsulation layer 145 can include an inorganic insulating material. For example, the third encapsulation layer 145 can include at least one inorganic insulating material among silicon nitride (SiNx), silicon oxide (SiOx), and silicon oxynitride (SiON).

A second buffer part 151 can be disposed on the encapsulation layer 140. A color filter 153 and a blocking layer 155 can be disposed on the second buffer part 151. The blocking layer 155 can be disposed on both sides of the color filter 153. The blocking layer 155 serves to separate each sub-pixel area and to prevent optical interference between adjacent sub-pixel areas. An optical carrier layer 160 is formed on the color filter 153 and the blocking layer 155. In addition, a protective member can be disposed on the optical carrier layer 160.

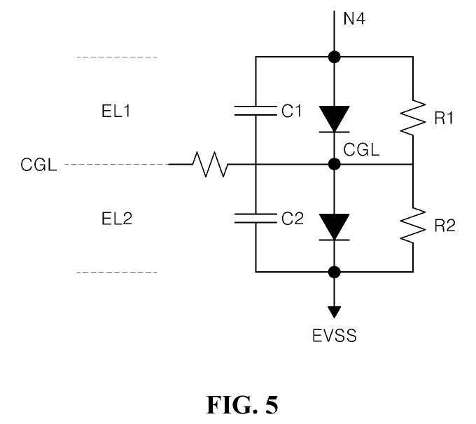

FIG. 4 is a circuit diagram of a pixel in an organic light-emitting display apparatus according to an embodiment of the present disclosure. FIG. 5 illustrates an equivalent circuit of the tandem light-emitting element of FIG. 4 according to an embodiment of the present disclosure.

Referring to FIGS. 4 and 5, each of the plurality of pixels P includes a tandem light-emitting element T_OLED and a pixel circuit that drives the tandem light-emitting element T_OLED. The pixel circuit includes a driving transistor DT, first to eighth transistors T1 to T8, and a storage capacitor Cst. Each of the driving transistor DT and the first through eighth transistors T1 through T8 can include a first electrode, a second electrode, and a gate electrode. One of the first and second electrodes can be a source electrode, and the other can be a drain electrode.

Each of the driving transistor DT and the first to eighth transistors T1 to T8 can be a P-type thin-film transistor or an N-type thin-film transistor. For example, the driving transistor DT and the second, third, fifth, sixth, seventh, and eighth transistors T2, T3, T5, T6, T7, and T8 can be P-type thin-film transistors, while the first and fourth transistors T1 and T4 can be N-type thin-film transistors.

According to one example, the first transistor T1 can function as a transistor compensating for the characteristics of the driving transistor DT, such as threshold voltage and mobility, the second transistor T2 can supply a data voltage Vdata, the third transistor T3 can supply a bias voltage Vobs, the fourth transistor T4 can initialize the storage capacitor Cst and the gate electrode of the driving transistor DT, the fifth and sixth transistors T5 and T6 can control the emission time of the tandem light-emitting element T_OLED, and the seventh and eighth transistors T7 and T8 can reset the anode electrode and the charge generation layer CGL of the tandem light-emitting element T_OLED.

The tandem light-emitting element T_OLED includes a first light-emitting element EL1 and a second light-emitting element EL2 connected in series. The node between the first light-emitting element EL1 and the second light-emitting element EL2 can be the charge generation layer CGL shown in FIGS. 2 and 3 or the refresh electrode 138 electrically connected to the charge generation layer CGL. The anode electrode of the tandem light-emitting element T_OLED is connected to the fourth node N4, and the cathode electrode is connected to the low-potential driving voltage EVSS.

The driving transistor DT can include a first electrode connected to the first node N1, a gate electrode connected to the second node N2, and a second electrode connected to the third node N3. The driving transistor DT controls the driving current Ids to emit light from the tandem light-emitting element T_OLED based on the voltage at the second node N2, for example, the data voltage Vdata sampled by the storage capacitor Cst.

The first transistor T1 includes a first electrode connected to the gate electrode of the driving transistor DT, a second electrode connected to the second electrode of the driving transistor DT, and a gate electrode receiving the first scan signal SC1. The first transistor T1 turns on in response to the first scan signal SC1 and samples the threshold voltage of the driving transistor DT to the storage capacitor Cst by connecting the driving transistor DT.

The storage capacitor Cst can be connected between a terminal to which the high-potential driving voltage EVDD is applied and the second node N2 corresponding to the gate electrode of the driving transistor DT. The storage capacitor Cst can sample the threshold voltage of the driving transistor DT or the data voltage Vdata based on the operation of the pixel circuit.

The second transistor T2 can include a first electrode connected to the data line DL supplying the data voltage Vdata, a second electrode connected to the first node N1 corresponding to the first electrode of the driving transistor DT, and a gate electrode receiving the second scan signal SC2. The second transistor T2 turns on in response to the second scan signal SC2 and transfers the data voltage Vdata to the first node N1.

The third transistor T3 can include a first electrode receiving the bias voltage Vobs, a second electrode connected to the first node N1 corresponding to the first electrode of the driving transistor DT, and a gate electrode receiving the third scan signal SC3. The third transistor T3 can supply the bias voltage Vobs to the first electrode of the driving transistor DT in response to the third scan signal SC3.

The fourth transistor T4 can include a first electrode receiving the initialization voltage Vini, a second electrode connected to the second node N2 corresponding to the gate electrode of the driving transistor DT, and a gate electrode receiving the fourth scan signal SC4. The fourth transistor T4 can initialize the gate electrode of the driving transistor DT and the storage capacitor Cst by supplying the initialization voltage Vini to the gate electrode of the driving transistor DT and the storage capacitor Cst in response to the fourth scan signal SC4.

The fifth transistor T5 can include a first electrode receiving the high-potential driving voltage EVDD, a second electrode connected to the first node N1 corresponding to the first electrode of the driving transistor DT, and a gate electrode receiving the emission control signal EM.

The sixth transistor T6 can include a first electrode connected to the third node N3 corresponding to the second electrode of the driving transistor DT, a second electrode connected to the fourth node N4 corresponding to the anode electrode of the tandem light-emitting element T_OLED, and a gate electrode receiving the emission control signal EM.

The fifth and sixth transistors T5 and T6 turn on in response to the emission control signal EM and form a current path for the driving current controlled by the driving transistor DT between the high-potential driving voltage EVDD and the low-potential driving voltage EVSS. The fifth and sixth transistors T5 and T6 can control the emission time of the tandem light-emitting element T_OLED by adjusting the turn-on time.

The seventh transistor T7 can include a first electrode receiving the anode reset voltage Var, a second electrode connected to the fourth node N4 corresponding to the anode electrode of the tandem light-emitting element T_OLED, and a gate electrode receiving the third scan signal SC3.

The seventh transistor T7 can turn on in response to the third scan signal SC3 and supply the anode reset voltage Var to the anode electrode of the tandem light-emitting element T_OLED, thereby resetting the anode electrode of the tandem light-emitting element T_OLED. The seventh transistor T7 can supply the anode reset voltage Var to the anode electrode of the tandem light-emitting element T_OLED either before or after the emission of the tandem light-emitting element T_OLED.

The eighth transistor T8 can include a first electrode receiving the anode reset voltage Var, a second electrode connected to the charge generation layer CGL of the tandem light-emitting element T_OLED, and a gate electrode receiving the third scan signal SC3.

The eighth transistor T8 can turn on in response to the third scan signal SC3 and supply the anode reset voltage Var to the charge generation layer CGL of the tandem light-emitting element T_OLED, thereby resetting the charge generation layer CGL of the tandem light-emitting element T_OLED. The eighth transistor T8 can supply the anode reset voltage Var to the charge generation layer CGL of the tandem light-emitting element T_OLED either before or after the emission of the tandem light-emitting element T_OLED.

Referring to FIG. 5, the tandem light-emitting element T_OLED includes a first light-emitting element EL1 and a second light-emitting element EL2. The tandem light-emitting element T_OLED can have a first parasitic capacitor C1 formed between the anode electrode and the charge generation layer CGL, and a second parasitic capacitor C2 formed between the charge generation layer CGL and the cathode electrode. Additionally, the tandem light-emitting element T_OLED can have a first parasitic resistor R1 formed between the anode electrode and the charge generation layer CGL, and a second parasitic resistor R2 formed between the charge generation layer CGL and the cathode electrode. The first and second parasitic capacitors C1 and C2 can have different capacitance values. Additionally, the first and second parasitic resistors R1 and R2 can have different resistance values.

The potential difference between the first and second light-emitting elements EL1 and EL2, i.e., the voltage across the charge generation layer CGL, can vary due to the first and second parasitic capacitors C1 and C2, or the first and second parasitic resistors R1 and R2. The voltage fluctuation across the charge generation layer CGL can cause the first or second light-emitting element EL1 or EL2 to emit light at an unintended time.

The pixel circuit can reset the charge generation layer CGL of the tandem light-emitting element T_OLED by supplying the anode reset voltage Var to the charge generation layer CGL through the eighth transistor T8.

The display apparatus according to an embodiment of the present disclosure can operate as a VRR mode display apparatus. The VRR mode can operate pixels by driving at a constant frequency and increasing the refresh rate at which the data voltage Vdata is updated when high-speed driving is required, or lowering the refresh rate to reduce power consumption or when low-speed driving is needed.

The pixel circuit can be driven through a combination of a refresh frame and an anode reset frame. In the present disclosure, the refresh frame can be defined as a period during which the data voltage Vdata is updated, and the anode reset frame can be defined as a period during which the data voltage Vdata is not updated. One frame can be driven solely by a refresh frame according to the refresh rate or by alternating refresh frames and anode reset frames.

For example, driving at a refresh rate of 120 Hz can involve only refresh frames. Driving at a refresh rate of 60 Hz can involve alternating refresh frames and anode reset frames. Driving at a refresh rate of 1 Hz can involve one frame consisting of one refresh frame followed by 119 anode reset frames. Additionally, driving at a refresh rate of 1 Hz can involve one frame consisting of a plurality of refresh frames and a plurality of anode reset frames.

The refresh frame charges a new data voltage Vdata, applying new data voltage Vdata to driving transistor DT, while anode reset frame retains and uses data voltage Vdata from previous frame. The anode reset frame can be named a skip or hold period, meaning the process of applying a new data voltage Vdata to the driving transistor DT is omitted.

The pixel circuit can eliminate the influence of the data voltage Vdata stored in the previous frame by initializing the gate electrode of the driving transistor DT and the storage capacitor Cst during the refresh frame. Additionally, the pixel circuit can reset the charge remaining on the anode electrode and the charge generation layer CGL of the tandem light-emitting element T_OLED during the refresh frame, thereby eliminating the influence of leakage current.

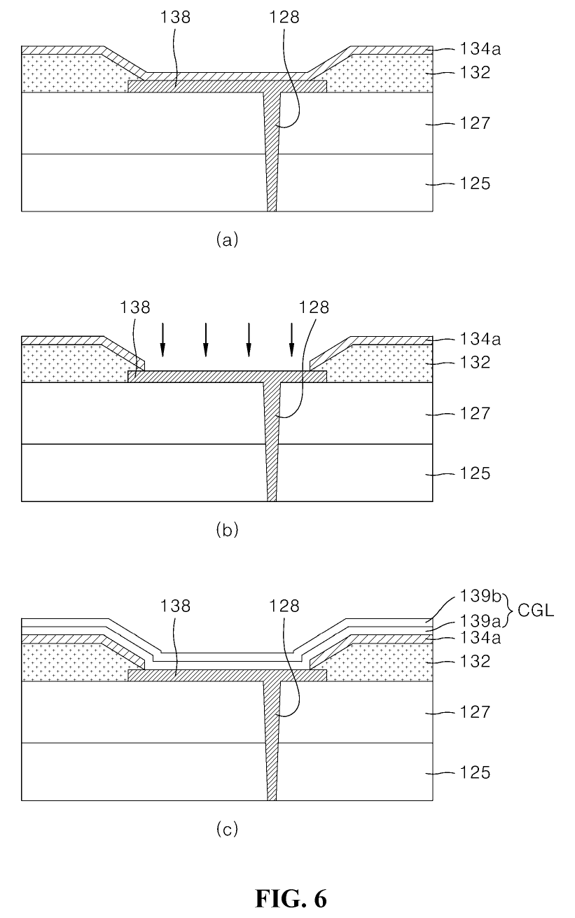

FIG. 6 shows diagrams illustrating the process flow of depositing the CGL on a refresh electrode 138 in FIG. 2 according to an embodiment of the present disclosure.

Referring to (a) of FIG. 6, the refresh electrode 138 is positioned over a portion of the second planarization layer 127. One surface of the refresh electrode 138 contacts the upper surface of the third contact electrode 128. The refresh electrode 138 can be connected to the second electrode of the eighth transistor T8 (see FIG. 4) via the third contact electrode 128, which fills the contact holes of the first and second planarization layers 125 and 127.

The bank 132 can be formed to cover the edges of the refresh electrode 138. A first light-emitting layer 134a is then deposited on top of the refresh electrode 138 and the bank 132.

Referring to (b) of FIG. 6, subsequently, the first light-emitting layer 134a deposited on top of the refresh electrode 138 is selectively removed. For example, the first light-emitting layer 134a deposited on the refresh electrode 138 can be selectively removed through laser drilling.

Referring to (c) of FIG. 6, next, an N-type charge generation layer 139a is deposited on top of the first light-emitting layer 134a and the refresh electrode 138. Then, a P-type charge generation layer 139b is deposited on top of the N-type charge generation layer 139a. Through this process, the refresh electrode 138 can be electrically connected to the charge generation layer CGL.

The charge generation layer CGL of the tandem light-emitting element T_OLED can be reset by receiving the anode reset voltage Var from the eighth transistor T8 (see FIG. 4) before or after the tandem light-emitting element T_OLED emits light. The light-emitting circuit can reset the charge remaining on the charge generation layer CGL of the tandem light-emitting element T_OLED during the refresh frame, preventing unwanted pixels from emitting light due to leakage current.

The pixel circuit according to this embodiment can reduce the influence of parasitic capacitors and resistors of the tandem light-emitting element T_OLED, as well as leakage current from adjacent pixels, by resetting the charge generation layer CGL during the bias period of the refresh frame and the anode reset frame.

In the present disclosure, the bias period is defined as the period for resetting the first node N1 corresponding to the first electrode of the driving transistor DT, the fourth node N4 corresponding to the anode electrode of the tandem light-emitting element T_OLED, and the charge generation layer CGL of the tandem light-emitting element T_OLED.

The pixel circuit can reset the first node N1 during the bias period by supplying a bias voltage Vobs to the first electrode of the driving transistor DT through the third transistor T3 (see FIG. 4). Additionally, the pixel circuit can reset the fourth node N4 during the bias period by supplying an anode reset voltage Var to the anode electrode of the tandem light-emitting element T_OLED through the seventh transistor T7 (see FIG. 4). Furthermore, the pixel circuit can reset the charge generation layer CGL during the bias period by supplying an anode reset voltage Var to the charge generation layer CGL of the tandem light-emitting element T_OLED through the eighth transistor T8 (see FIG. 4).

The third, seventh, and eighth transistors T3, T7, and T8 can turn on in response to an enable scan signal SC3 during the bias periods of the refresh frame and the anode reset frame. The scan signal SC3 can be applied at a low level during the bias periods of the refresh frame and the anode reset frame.

A display apparatus according to one or more embodiments of the present disclosure includes a display panel comprising a plurality of pixels arranged thereon, wherein the plurality of pixels each include a tandem light-emitting element comprising a first and second light-emitting element connected in series, a driving transistor configured to drive the tandem light-emitting element, and a reset transistor configured to apply a reset voltage to a node between the first and second light-emitting elements.

According to an embodiment of the present disclosure, the reset transistor can reset the node between the first and second light-emitting elements during a period for resetting the anode electrode of the tandem light-emitting element.

According to an embodiment of the present disclosure, the reset transistor can reset the node between the first and second light-emitting elements in response to a scan signal applied during the bias periods of a refresh frame and an anode reset frame.

According to an embodiment of the present disclosure, the tandem light-emitting element can include an anode electrode, a first light-emitting layer disposed on the anode electrode, a charge generation layer disposed on the first light-emitting layer, a second light-emitting layer disposed on the charge generation layer, and a cathode electrode disposed on the second light-emitting layer, wherein the charge generation layer can correspond to the node between the first and second light-emitting elements.

According to an embodiment of the present disclosure, the charge generation layer can be electrically connected to a source or drain electrode of the reset transistor.

According to an embodiment of the present disclosure, the reset transistor can be disposed in a transistor array layer of the pixel and can include a contact electrode filling a contact hole penetrating a protective layer, a first planarization layer, and a second planarization layer formed in the transistor array layer, and connected to the source or drain electrode of the reset transistor, and a refresh electrode disposed on the second planarization layer and connected to the upper surface of the contact electrode.

According to an embodiment of the present disclosure, the charge generation layer can be disposed on the refresh electrode.

According to an embodiment of the present disclosure, the charge generation layer can be electrically connected to the source or drain electrode of the transistor through the refresh electrode and the contact electrode.

A display apparatus according to an embodiment of the present disclosure includes a display panel comprising a plurality of pixels arranged thereon, wherein the plurality of pixels each include a tandem light-emitting element comprising a first and second light-emitting element connected in series, a driving transistor configured to drive the tandem light-emitting element, a storage capacitor with one electrode connected to a high-potential driving voltage and the other electrode connected to the gate electrode of the driving transistor, a first transistor with one electrode connected to the gate electrode of the driving transistor and the other electrode connected to the drain electrode of the driving transistor, a second transistor with one electrode connected to the source electrode of the driving transistor and the other electrode connected to a data voltage, a third transistor with one electrode connected to the source electrode of the driving transistor and the other electrode connected to a bias voltage, a fourth transistor with one electrode connected to the other electrode of the storage capacitor and the other electrode connected to an initialization voltage, a fifth transistor with one electrode connected to a high-potential driving voltage and the other electrode connected to the source electrode of the driving transistor, a sixth transistor with one electrode connected to the drain electrode of the driving transistor and the other electrode connected to the anode electrode of the tandem light-emitting element, a seventh transistor with one electrode connected to an anode reset voltage and the other electrode connected to the anode electrode of the tandem light-emitting element, and an eighth transistor with one electrode connected to an anode reset voltage and the other electrode connected to the node between the first and second light-emitting elements.

According to an embodiment of the present disclosure, the eighth transistor can reset the node between the first and second light-emitting elements during a period for resetting the anode electrode of the tandem light-emitting element.

According to an embodiment of the present disclosure, the third, seventh, and eighth transistors can turn on in response to the same scan signal.

According to an embodiment of the present disclosure, the scan signal is enabled during the bias periods of a refresh frame and an anode reset frame.

According to an embodiment of the present disclosure, the tandem light-emitting element can include an anode electrode, a first light-emitting layer disposed on the anode electrode, a charge generation layer disposed on the first light-emitting layer, a second light-emitting layer disposed on the charge generation layer, and a cathode electrode disposed on the second light-emitting layer, wherein the charge generation layer can correspond to the node between the first and second light-emitting elements.

According to an embodiment of the present disclosure, the charge generation layer can be electrically connected to the source or drain electrode of the eighth transistor.

According to an embodiment of the present disclosure, the eighth transistor can be disposed in the transistor array layer of the pixel and can include a contact electrode filling a contact hole penetrating a protective layer, a first planarization layer, and a second planarization layer formed in the transistor array layer, and connected to the source or drain electrode of the eighth transistor, and a refresh electrode disposed on the second planarization layer and connected to the upper surface of the contact electrode.

According to an embodiment of the present disclosure, the charge generation layer can be disposed on the refresh electrode.

According to an embodiment of the present disclosure, the charge generation layer can be electrically connected to the source or drain electrode of the eighth transistor through the refresh electrode and the contact electrode.

Although embodiments of the present disclosure have been described in detail with reference to the accompanying drawings, it should be noted that the present disclosure is not necessarily limited to these embodiments and can be modified in various ways without departing from the scope of the technical concept of the invention. Therefore, the embodiments disclosed in this specification are not intended to limit but to describe the technical idea of the present disclosure, and the scope of the technical idea of the present disclosure is not limited by the embodiments. Therefore, it should be understood that the embodiments described above are examples and not limited in all aspects.

What is claimed is:

1. A display apparatus comprising:
a display panel comprising a plurality of pixels arranged thereon,
wherein each of the plurality of pixels comprises:
a tandem light-emitting element comprising a first light-emitting element and a second light-emitting element that are connected in series;
a driving transistor configured to drive the tandem light-emitting element; and
a reset transistor configured to apply a reset voltage to a node between the first and second light-emitting elements.

2. The display apparatus of claim 1, wherein the reset transistor resets the node between the first and second light-emitting elements during a period for resetting an anode electrode of the tandem light-emitting element.

3. The display apparatus of claim 1, wherein the reset transistor resets the node between the first and second light-emitting elements in response to a scan signal applied during bias periods of a refresh frame and an anode reset frame.

4. The display apparatus of claim 1, wherein the tandem light-emitting element comprises:
an anode electrode;
a first light-emitting layer disposed on the anode electrode;
a charge generation layer disposed on the first light-emitting layer;
a second light-emitting layer disposed on the charge generation layer; and
a cathode electrode disposed on the second light-emitting layer, and
wherein the charge generation layer corresponds to the node between the first and second light-emitting elements.

5. The display apparatus of claim 4, wherein the charge generation layer is electrically connected to a source or drain electrode of the reset transistor.

6. The display apparatus of claim 4, wherein the reset transistor is disposed in a transistor array layer of the pixel and comprises:
a contact electrode filling a contact hole penetrating a protective layer, a first planarization layer, and a second planarization layer disposed in the transistor array layer, and connected to a source or drain electrode of the reset transistor; and
a refresh electrode disposed on the second planarization layer and connected to an upper surface of the contact electrode.

7. The display apparatus of claim 6, wherein the charge generation layer is disposed on the refresh electrode.

8. The display apparatus of claim 7, wherein the charge generation layer is electrically connected to a source or drain electrode of the reset transistor through the refresh electrode and the contact electrode.

9. The display apparatus of claim 1, wherein a gate electrode of the driving transistor and a storage capacitor of the pixel are initialized during a refresh frame.

10. A display apparatus comprising:
a display panel comprising a plurality of pixels arranged thereon,
wherein each of the plurality of pixels comprises:
a tandem light-emitting element comprising a first light-emitting element and a second light-emitting element that are connected in series;
a driving transistor configured to drive the tandem light-emitting element;
a storage capacitor having one electrode connected to a high-potential driving voltage and another electrode connected to a gate electrode of the driving transistor;
a first transistor having one electrode connected to the gate electrode of the driving transistor and another electrode connected to a drain electrode of the driving transistor;
a second transistor having one electrode connected to a source electrode of the driving transistor and another electrode connected to a data voltage;
a third transistor having one electrode connected to the source electrode of the driving transistor and another electrode connected to a bias voltage;
a fourth transistor having one electrode connected to the another electrode of the storage capacitor and another electrode connected to an initialization voltage;
a fifth transistor having one electrode connected to a high-potential driving voltage and another electrode connected to the source electrode of the driving transistor;
a sixth transistor having one electrode connected to the drain electrode of the driving transistor and another electrode connected to an anode electrode of the tandem light-emitting element;
a seventh transistor having one electrode connected to an anode reset voltage and another electrode connected to the anode electrode of the tandem light-emitting element; and
an eighth transistor having one electrode connected to an anode reset voltage and another electrode connected to the node between the first and second light-emitting elements.

11. The display apparatus of claim 10, wherein the eighth transistor resets the node between the first and second light-emitting elements during a period for resetting the anode electrode of the tandem light-emitting element.

12. The display apparatus of claim 10, wherein the third, seventh, and eighth transistors turn on in response to a same scan signal.

13. The display apparatus of claim 12, wherein the same scan signal is enabled during bias periods of a refresh frame and an anode reset frame.

14. The display apparatus of claim 10, wherein the tandem light-emitting element comprises:
an anode electrode;
a first light-emitting layer disposed on the anode electrode;
a charge generation layer disposed on the first light-emitting layer;
a second light-emitting layer disposed on the charge generation layer; and
a cathode electrode disposed on the second light-emitting layer,
wherein the charge generation layer corresponds to the node between the first and second light-emitting elements.

15. The display apparatus of claim 14, wherein the charge generation layer is electrically connected to a source or drain electrode of the eighth transistor.

16. The display apparatus of claim 14, wherein the eighth transistor is disposed in a transistor array layer of the pixel and comprises:
a contact electrode filling a contact hole penetrating a protective layer, a first planarization layer, and a second planarization layer formed in the transistor array layer, and connected to a source or drain electrode of the eighth transistor; and
a refresh electrode disposed on the second planarization layer and connected to an upper surface of the contact electrode.

17. The display apparatus of claim 16, wherein the charge generation layer is disposed on the refresh electrode.

18. The display apparatus of claim 17, wherein the charge generation layer is electrically connected to the source or drain electrode of the eighth transistor through the refresh electrode and the contact electrode.
